(19) United States
(12) Patent Application Publication
(10) Pub. No.: US 2026/0150674 A1
(43) Pub. Date: May 28, 2026

(54) SEMICONDUCTOR PACAKGE AND METHOD OF FABRICATING THE SAME

(71) Applicant: Taiwan Semiconductor Manufacturing Company, Ltd., Hsinchu (TW)

(72) Inventors: Yen-Ming Chen, Hsinchu County (TW); Kuo-Chiang Ting, Hsinchu City (TW); Ting-Chu Ko, Hsinchu (TW)

(73) Assignee: Taiwan Semiconductor Manufacturing Company, Ltd., Hsinchu (TW)

(21) Appl. No.: 19/182,573

(22) Filed: Apr. 17, 2025

Related U.S. Application Data
(60) Provisional application No. 63/724,396, filed on Nov. 24, 2024.

(51) Int. Cl. H01L 23/373; H01L 23/367; H01L 23/544

(52) U.S. Cl. CPC H10W 40/254; H10W 40/22; H10W 46/00

(57) ABSTRACT

A semiconductor package includes a first die, at least one second die and a thermal dissipation structure. The first die has a first bonding layer. The second die has a second bonding layer, wherein the second die is disposed on the first die, and the second bonding layer is bonded to the first bonding layer. The thermal dissipation structure is disposed on a backside surface of the at least one second die, wherein a thermal conductivity of the thermal dissipation structure is in a range of 120 W/(m·K) to 10,000 W/(m·K), a thickness of the thermal dissipation structure is in a range of 5 μm to 1,500 μm, and an area of a surface of the thermal dissipation structure facing the backside surface of the at least one second die is in a range of 10 mm² to 860 mm².

### CROSS-REFERENCE TO RELATED APPLICATION

This application claims the priority benefits of U.S. provisional application Ser. No. 63/724,396, filed on Nov. 24, 2024. The entirety of the above-mentioned patent application is hereby incorporated by reference herein and made a part of this specification.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies, and with improved thermal solution has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the critical dimensions of the various features may be arbitrarily increased or reduced for clarity of discussion.

FIG. 1 to FIG. 7 are schematic sectional views of various stages in a method of fabricating a package structure according to some exemplary embodiments of the present disclosure.

FIG. 8 is a schematic sectional view of a package structure according to some other exemplary embodiments of the present disclosure.

FIG. 9 to FIG. 10 are schematic sectional views of various stages in a method of fabricating a package structure according to some other exemplary embodiments of the present disclosure.

FIG. 11 to FIG. 15 are schematic sectional views of various stages in a method of fabricating a package structure according to some other exemplary embodiments of the present disclosure.

FIG. 16 is a schematic sectional view of a package structure according to some other exemplary embodiments of the present disclosure.

FIG. 17 is a schematic sectional view of a package structure according to some other exemplary embodiments of the present disclosure.

FIG. 18 is a schematic sectional view of a package structure according to some other exemplary embodiments of the present disclosure.

FIG. 19 is a schematic sectional view of a package structure according to some other exemplary embodiments of the present disclosure.

FIG. 20 is a schematic sectional view of a package structure according to some other exemplary embodiments of the present disclosure.

FIG. 21 is a schematic sectional view of a package structure according to some other exemplary embodiments of the present disclosure.

FIG. 22 is a schematic sectional view of a package structure according to some other exemplary embodiments of the present disclosure.

FIG. 23A to FIG. 23D are schematic bottom views of the package structure according to various embodiments of the present disclosure.

FIG. 24 is a schematic sectional view of a semiconductor package according to some exemplary embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In three-dimensional integrated circuit (3DIC) stacking structures such as system on integrated chips (SoIC), thermal dissipation is an issue that needs to be considered for improving the performance of the package. In accordance with some embodiments of the present disclosure, silicon carriers are replaced with a thermal dissipation material having a lowered thermal resistance, which will provide an improved thermal solution for 3DIC stacking.

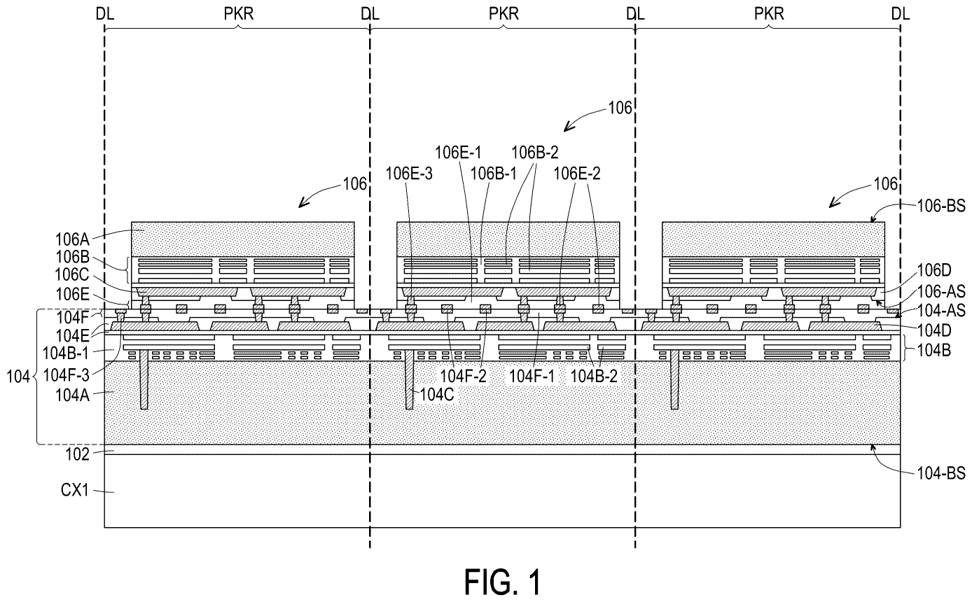

FIG. 1 to FIG. 7 are schematic sectional views of various stages in a method of fabricating a package structure according to some exemplary embodiments of the present disclosure. Referring to FIG. 1, a first carrier CX1 is provided. In some embodiments, the first carrier CX1 may be a glass carrier or any suitable carrier for carrying a semiconductor wafer or a reconstituted wafer for the manufacturing method of the semiconductor package. In some embodiments, the first carrier CX1 is coated with a debond layer 102. The material of the debond layer 102 may be any material suitable for bonding and de-bonding the first carrier CX1 from the above layer(s) or any wafer(s) disposed thereon.

In some embodiments, the debond layer 102 may include a dielectric material layer made of a dielectric material including any suitable polymer-based dielectric material (such as benzocyclobutene (“BCB”), polybenzoxazole (“PBO”)). In an alternative embodiment, the debond layer 102 may include a dielectric material layer made of an epoxy-based thermal-release material, which loses its adhesive property when heated, such as a light-to-heat-conversion (LTHC) release coating film. In a further alternative embodiment, the debond layer 102 may include a dielectric material layer made of an ultra-violet (UV) glue, which loses its adhesive property when exposed to UV lights. In certain embodiments, the debond layer 102 may be dispensed as a liquid and cured, or may be a laminate film laminated onto the first carrier CX1, or may be the like. The top surface of the debond layer 102, which is opposite to a bottom surface contacting the first carrier CX1, may be leveled and may have a high degree of coplanarity. In certain embodiments, the debond layer 102 is, for example, a LTHC layer with good chemical resistance, and such layer enables room temperature de-bonding from the first carrier CX1 by applying laser irradiation, however the disclosure is not limited thereto.

In an alternative embodiment, a buffer layer (not shown) may be coated on the debond layer 102, where the debond layer 102 is sandwiched between the buffer layer and the first carrier CX1, and the top surface of the buffer layer may further provide a high degree of coplanarity. In some embodiments, the buffer layer may be a dielectric material layer. In some embodiments, the buffer layer may be a polymer layer which made of polyimide, polybenzoxazole (PBO), benzocyclobutene (BCB), or any other suitable polymer-based dielectric material. In some embodiments, the buffer layer may be Ajinomoto Buildup Film (ABF), Solder Resist film (SR), or the like. In other words, the buffer layer is optional and may be omitted based on the demand, so that the disclosure is not limited thereto.

Referring to FIG. 1, in a subsequent step, a first die 104 is formed on the debond layer 102. In some embodiments, the first die 104 is part of a semiconductor wafer. In other words, the semiconductor wafer is formed on the debond layer 102, and may include one or a plurality of the first dies 104. In the exemplary embodiment, the first die 104 is formed with a semiconductor substrate 104A, a redistribution structure 104B, through substrate vias 104C, conductive pads 104D, dielectric layers 104E and a first bonding layer 104F. As shown in FIG. 1, the first die 104 includes an active surface 104-AS and a backside surface 104-BS opposite to the active surface 104-AS. The active surface 104-AS of the first die 104 is a top surface of the dielectric layer 104E, whereby the conductive pads 104D are exposed, and whereby the first bonding layer 104F is formed thereon. The backside surface 104-BS of the first die 104 is a bottom surface of the semiconductor substrate 104A, whereby the backside surface 104-BS is contacting the debond layer 102.

In some embodiments, the semiconductor substrate 104A may be a bulk silicon substrate or a silicon-on-insulator (SOI) substrate, and further includes active devices (e.g., transistors or the like) and optionally passive devices (e.g., resistors, capacitors, inductors or the like) formed therein, or located thereon. In some embodiments, the redistribution structure 104B is disposed on the semiconductor substrate 104A, and contacting a top surface of the semiconductor substrate 104A. In some embodiments, the formation of the redistribution structure 104B includes forming a plurality of dielectric layers 104B-1 and a plurality of conductive elements 104B-2 that are alternately stacked. The number of layers of the dielectric layers 104B-1 and the number of layers of the conductive elements 104B-2 is not particularly limited in the disclosure, and may be adjusted based on product requirements.

In some embodiments, a material of the dielectric layers 104B-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 104B-1 may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive elements 104B-2 may be made of conductive materials formed by electroplating or deposition, such as aluminum, titanium, copper, nickel, tungsten, and/or alloys thereof, which may be patterned using a photolithography and etching process. In some embodiments, the conductive elements 104B-2 may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

In some embodiments, the through substrate vias 104C extend from the redistribution structure 104B to the semiconductor substrate 104A, and are embedded in the semiconductor substrate 104A. In certain embodiments, the through substrate vias 104C are electrically connected to the conductive elements 104B-2 of the redistribution structure 104B. The through substrate vias 104C may be formed of conductive materials, such as copper, copper alloys, or the like, and may be formed by plating or deposition.

As further illustrated in FIG. 1, conductive pads 104D and dielectric layers 104E are formed on the redistribution structure 104B. For example, the conductive pads 104D are disposed on one of the dielectric layers 104E, and are electrically connected to the conductive elements 104B-2 of the redistribution structure 104B. In some embodiments, the dielectric layers 104E may be further formed on the conductive pads 104D to partially cover the conductive pads 104D. In other words, portions of the conductive pads 104D are exposed by the dielectric layer 104E. In the exemplary embodiment, the conductive pads 104D include materials such as copper, nickel, titanium, tungsten, or alloys thereof or the like, and may be formed by an electroplating process, for example. Furthermore, the dielectric layers 104E are formed by depositing a dielectric material, such as silicon oxide, silicon nitride, or the like, whereby the dielectric layers 104E may be patterned using a photolithography and/or etching process.

In some embodiments, the first bonding layer 104F is formed on dielectric layers 104E and on the conductive pads 104D. For example, forming the first bonding layer 104F includes forming a dielectric layer 104F-1 and a plurality of bonding pads 104F-2 embedded in the dielectric layer 104F-1. In some embodiments, the bonding pads 104F-2 may be electrically connected to the conductive pads 104D through a plurality of conductive vias 104F-3. In some embodiments, the bonding pads 104F-2 and the conductive vias 104F-3 are made of conductive materials formed by electroplating or deposition, and include materials such as copper, copper alloys, or other suitable metallic materials which may be patterned using a photolithography and etching process. Furthermore, the dielectric layer 104F-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 104F-1 is formed by suitable fabrication techniques such as spin-on coating, chemical vapor deposition (CVD), plasma-enhanced chemical vapor deposition (PECVD) or the like. The disclosure is not limited thereto.

After forming the first bonding layer 104F, the formation of the first die 104 (or wafer including the first die 104) is accomplished. As illustrated in FIG. 1, the first die 104 has a plurality of package regions PKR and a dicing line DL separating each of the plurality of package regions PKR. In some embodiments, after forming the first die 104, a plurality of second dies 106 is formed. The second dies 106 are bonded to the first die 104 within each of the package regions PKR. In some embodiments, each of the second dies 106 is formed with a semiconductor substrate 106A, a redistribution structure 106B, conductive pads 106C, dielectric layers 106D and a second bonding layer 106E. As shown in FIG. 1, the second dies 106 includes an active surface 106-AS and a backside surface 106-BS opposite to the active surface 106-AS. The active surface 106-AS of the second die 106 is a top surface of the dielectric layer 106D, whereby the conductive pads 106C are exposed, and whereby the second bonding layer 106E is formed thereon. The backside surface 106-BS of the second die 106 is a bottom surface of the semiconductor substrate 106A. In the exemplary embodiment, the second dies 106 are bonded to the first die 104 so that the active surface 104-AS of the first die 104 is facing the active surface 106-AS of the second dies 106.

In some embodiments, the semiconductor substrate 106A may be a bulk silicon substrate or a silicon-on-insulator (SOI) substrate, and further includes active devices (e.g., transistors or the like) and optionally passive devices (e.g., resistors, capacitors, inductors or the like) formed therein, or located thereon. In some embodiments, the redistribution structure 106B is disposed on the semiconductor substrate 106A, and contacting a top surface of the semiconductor substrate 106A. In some embodiments, the formation of the redistribution structure 106B includes forming a plurality of dielectric layers 106B-1 and a plurality of conductive elements 106B-2 that are alternately stacked. The number of layers of the dielectric layers 106B-1 and the number of layers of the conductive elements 106B-2 is not particularly limited in the disclosure, and may be adjusted based on product requirements.

In some embodiments, a material of the dielectric layers 106B-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the material of the dielectric layers 106B-1 may be formed by suitable fabrication techniques such as spin-on coating, chemical vapor deposition (CVD), plasma-enhanced chemical vapor deposition (PECVD) or the like. The disclosure is not limited thereto.

In some embodiments, the conductive elements 106B-2 may be made of conductive materials formed by electroplating or deposition, such as aluminum, titanium, copper, nickel, tungsten, and/or alloys thereof, which may be patterned using a photolithography and etching process. In some embodiments, the conductive elements 106B-2 may be patterned copper layers or other suitable patterned metal layers. Throughout the description, the term “copper” is intended to include substantially pure elemental copper, copper containing unavoidable impurities, and copper alloys containing minor amounts of elements such as tantalum, indium, tin, zinc, manganese, chromium, titanium, germanium, strontium, platinum, magnesium, aluminum or zirconium, etc.

As further illustrated in FIG. 1, conductive pads 106C and dielectric layers 106D are formed on the redistribution structure 106B. For example, the conductive pads 106C are disposed on one of the dielectric layers 106D, and are electrically connected to the conductive elements 106B-2 of the redistribution structure 106B. In some embodiments, the dielectric layers 106D may be further formed on the conductive pads 106C to partially cover the conductive pads 106C. In other words, portions of the conductive pads 106C are exposed by the dielectric layer 106D. In the exemplary embodiment, the conductive pads 106C include materials such as copper, nickel, titanium, tungsten, or alloys thereof or the like, and may be formed by an electroplating process, for example. Furthermore, the dielectric layers 106D are formed by depositing a dielectric material, such as silicon oxide, silicon nitride, or the like, whereby the dielectric layers 106D may be patterned using a photolithography and/or etching process.

In some embodiments, the second bonding layer 106E is formed on the dielectric layers 106D and on the conductive pads 106C. For example, forming the second bonding layer 106E includes forming a dielectric layer 106E-1 and a plurality of bonding pads 106E-2 embedded in the dielectric layer 106E-1. In some embodiments, the bonding pads 106E-2 may be electrically connected to the conductive pads 106D through a plurality of conductive vias 106E-3. In some embodiments, the bonding pads 106E-2 and the conductive vias 106E-3 are made of conductive materials formed by electroplating or deposition, and include materials such as copper, copper alloys, or other suitable metallic materials which may be patterned using a photolithography and etching process. Furthermore, the dielectric layer 106E-1 may be polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like, which may be patterned using a photolithography and/or etching process. In some embodiments, the dielectric layer 106E-1 is formed by suitable fabrication techniques such as spin-on coating, chemical vapor deposition (CVD), plasma-enhanced chemical vapor deposition (PECVD) or the like. The disclosure is not limited thereto.

After forming the second bonding layer 106E, the formation of the second die 106 is accomplished. In the exemplary embodiment, the second dies 106 are bonded to the first die 104 by bonding the first bonding layer 104F to the second bonding layer 106E. For example, the dielectric layer 104F-1 is joined with the dielectric layer 106E-1 through dielectric-to-dielectric bonding, and the bonding pads 104F-2 are joined with the bonding pads 106E-2 through direct metal-to-metal bonding. In some embodiments, the second dies 106 are electrically connected to the first die 104 through the first bonding layer 104F and the second bonding layer 106E. In some embodiments, the first bonding layer 104F is joined to the second bonding layer 106E so that a portion of the bonding pads 104F-2 are revealed (uncovered) by the second dies 106. In other words, some of the bonding pads 104F-2 are dummy pads that do not have electrical connection with the second dies 106. Although one second die 106 is shown to be located on each of the package regions PKR of the first die 104, it is noted that the number of second dies 106 bonded to the first die 104 in each of the package regions PKR is not limited thereto, and may be adjusted based on product requirements. For example, in alternative embodiments, two or more of the second dies 106 may be located on each of the package regions PKR of the first die 104.

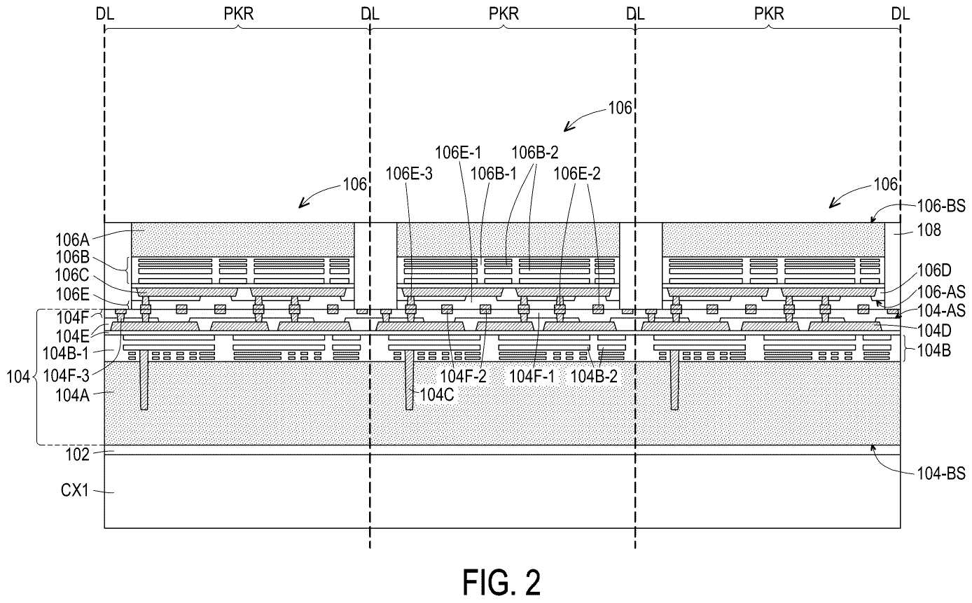

Referring to FIG. 2, after bonding the second dies 106 to the first die 104, a gap-filling layer 108 is formed on the first die 104 to laterally surround the second dies 106. In some embodiments, the gap-filling layer 108 is formed to cover a portion of the bonding pads 104F-2 of the first die 104. In some embodiments, the gap-filling layer 108 may be formed of a dielectric material, such as an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as chemical vapor deposition (CVD), atomic layer deposition (ALD), or the like. In some embodiments, a planarization process such as a chemical-mechanical polishing (CMP) process may be performed to partially remove the gap-filling layer 108. In certain embodiments, the backside surface 106-BS of the second dies 106 may also be partially removed through the planarization process. For example, after the planarization process, a top surface of the gap-filling layer 108 is substantially aligned with the backside surface 106-BS of the second dies 106.

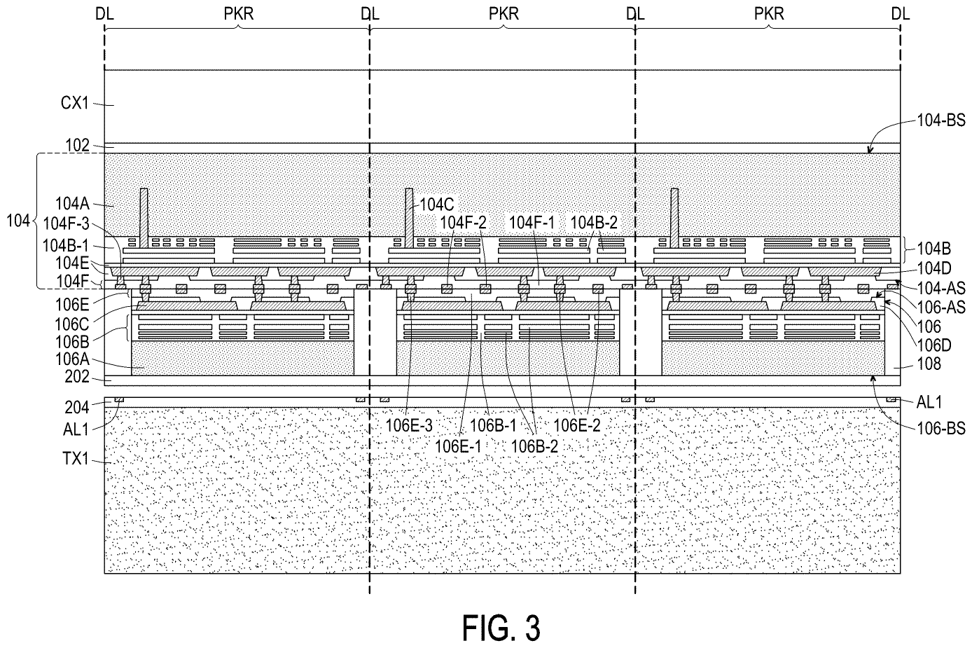

Referring to FIG. 3, in a subsequent step, the structure shown in FIG. 2 is turned upside down and bonded to a thermal dissipation structure TX1. For example, the bonding is achieved through a first film layer 202 and a second film layer 204. In some embodiments, the first film layer 202 is formed on the backside surface 106-BS of the second die 106 and contacting the backside surface 106-BS. Furthermore, the second film layer 204 is formed on a top surface of the thermal dissipation structure TX1. In the exemplary embodiment, the first film layer 202 and the second film layer 204 are made of dielectric materials such as polyimide, polybenzoxazole (PBO), benzocyclobutene (BCB), a nitride such as silicon nitride, an oxide such as silicon oxide, phosphosilicate glass (PSG), borosilicate glass (BSG), boron-doped phosphosilicate glass (BPSG), a combination thereof or the like. In some embodiments, the thermal dissipation structure TX1 is disposed on the second dies 106 by joining the first film layer 202 to the second film layer 202. For example, the first film layer 202 is bonded to the second film layer 204 through dielectric-to-dielectric bonding. In some alternative embodiments, the first film layer 202 and the second film layer 204 are omitted, and the bonding between the second dies 106 and the thermal dissipation structure TX1 may be achieved through the use of adhesives. In some embodiments, a plurality of alignment marks AL1 are formed and embedded in the second film layer 204 in each of the package regions PKR. For example, the alignments mark AL1 are made of conductive materials, such as copper, or the like.

In the exemplary embodiment, the thermal dissipation structure TX1 is formed of a low thermal resistance material, such as single crystal diamond (SCD), silicon carbide, or the like. In certain embodiments, the thermal dissipation structure TX1 is made of single crystal diamond (SCD). In some embodiments, the thermal dissipation structure TX1 may be made of a material having a thermal conductivity in a range of 120 W/(m·K) to 10,000 W/(m·K). In some embodiments, the thermal dissipation structure TX1 is formed with a thickness in a range of 5 μm to 1,500 μm. In certain embodiments, the thermal dissipation structure TX1 is formed with a thickness in a range of 5 μm to 775 μm. Furthermore, sidewalls of the thermal dissipation structure TX1 are aligned with sidewalls of the gap-filling layer 108, and aligned with sidewalls of the first die 104 (or wafer including the first die 104).

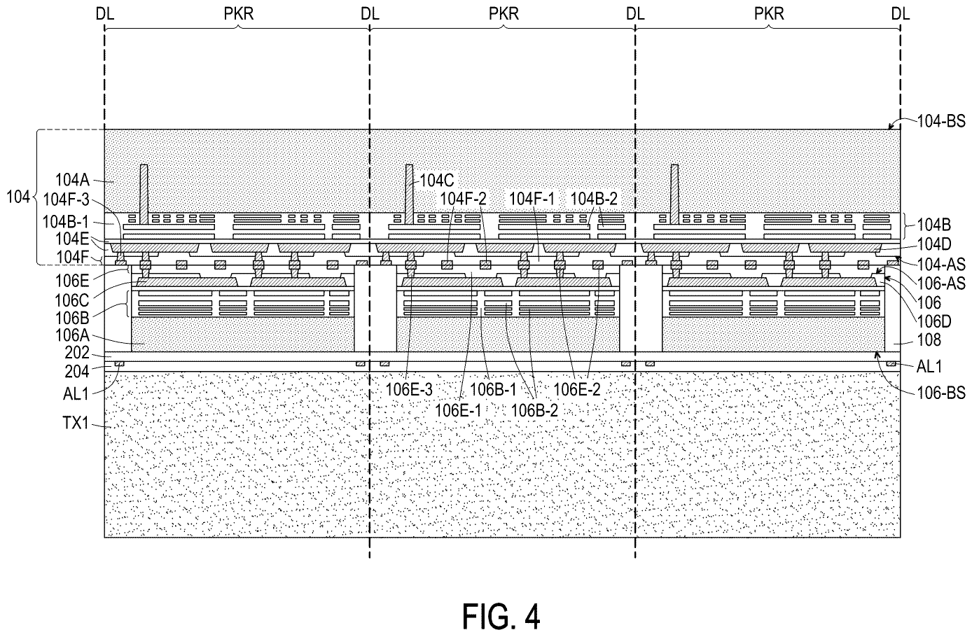

Referring to FIG. 4, after bonding a thermal dissipation structure TX1 over the backside surfaces 106-BS of the second dies 106, the first carrier CX1 is debonded/removed to separate the first die 104 from the first carrier CX1. In some embodiments, the debonding process include projecting a light such as a laser light or an UV light on the debond layer 102, so that the first carrier CX1 can be easily removed. As illustrated in FIG. 4, upon removing the first carrier CX1, the backside surface 104-BS of the first die 104 is exposed.

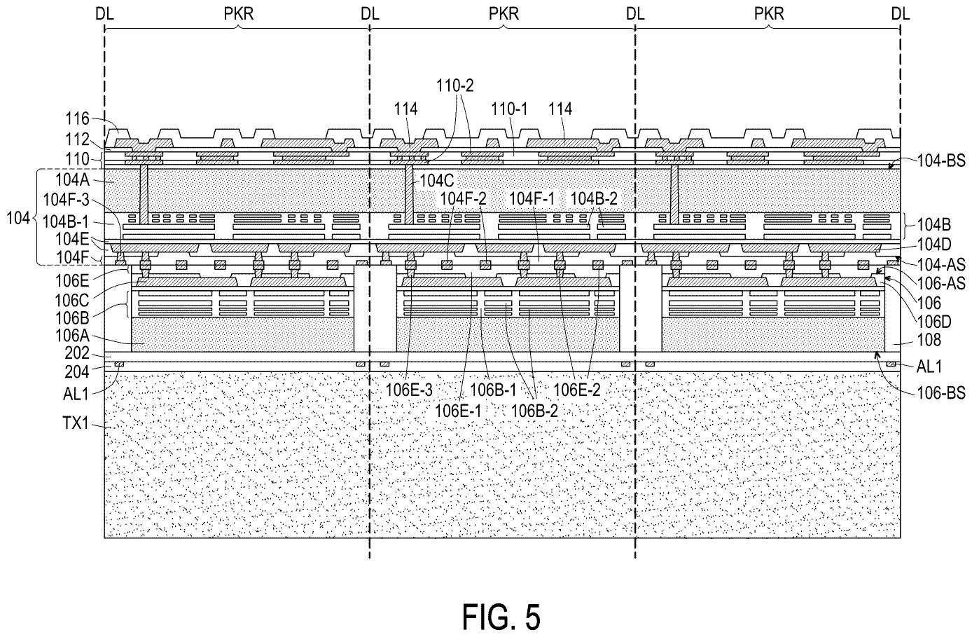

Referring to FIG. 5, in a subsequent step, after removing the first carrier CX1, the backside surface 104-BS of the first die 104 is thinned down to reveal the through substrate vias 104C. For example, the backside surface 104-BS of the first die 104 is ground or polished by a planarization step, such as a mechanical grinding process and/or a chemical mechanical polishing (CMP) process to reveal the through substrate vias 104C. Thereafter, a backside redistribution structure 110 is formed on the backside surface 104-BS of the first die 104. For example, the backside redistribution structure 110 is electrically connected to the through substrate vias 104C of the first die 104.

In some embodiments, the formation of the backside redistribution structure 110 includes forming a plurality of dielectric layers 110-1 and a plurality of conductive elements 110-2 that are alternately stacked. The number of layers of the dielectric layers 110-1 and the number of layers of the conductive elements 110-2 is not particularly limited in the disclosure, and may be adjusted based on product requirements. Furthermore, a material of the dielectric layers 110-1 and a material of the conductive elements 110-2 may be similar to a material of the dielectric layers 104B-1 and a material of the conductive elements 104B-2 of the first die 104. As such, the details of the dielectric layers 110-1 and the conductive elements 110-2 will not be repeated herein.

As further illustrated in FIG. 5, after forming the backside redistribution structure 110, a dielectric layer 112 is formed on the backside redistribution structure 110. In some embodiments, the dielectric layer 112 is patterned to form openings that reveal the conductive elements 110-2 of the backside redistribution structure 110. In a subsequent step, a plurality of conductive pads 114 is formed in the openings to be electrically connected to the conductive elements 110-2. In some embodiments, the conductive pads 114 are for example, under-ball metallurgy (UBM) patterns used for ball mount. In some embodiments, the materials of the conductive pads 114 may include copper, nickel, titanium, tungsten, or alloys thereof or the like, and may be formed by an electroplating process, for example. The number of conductive pads 114 are not limited in this disclosure, and may be selected based on the design layout. In some embodiments, a dielectric layer 116 may be formed on the conductive pads 114, whereby the dielectric layer 116 may be patterned to form openings revealing the conductive pads 114. In the exemplary embodiment, the dielectric layers 112 and 116 may include materials that are the same as the dielectric layers 110-1, thus the details will be omitted herein.

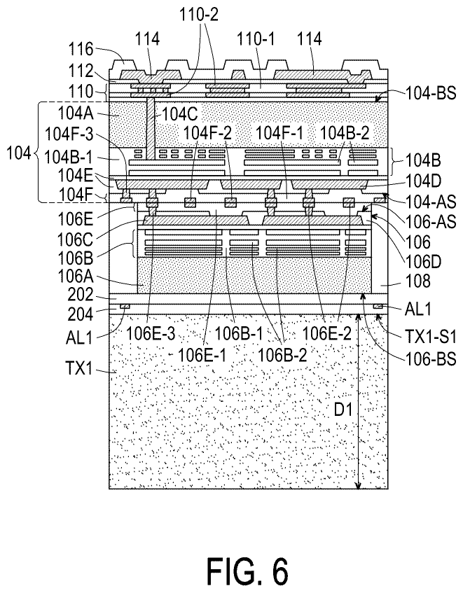

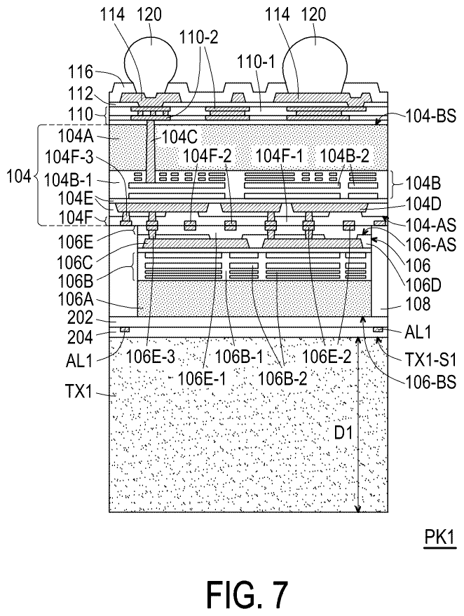

Referring to FIG. 6, the structure shown in FIG. 5 may be diced or singulated along the dicing lines DL to form separated packages. For example, the dicing process is performed to cut through the thermal dissipation structure TX1, the first film layer 202 and the second film layer 204, the gap-filling layer 108, the first die 104, the backside redistribution structure 110 and the dielectric layer 112. In some embodiments, the dicing process or the singulation process typically involves dicing with a rotating blade or a laser beam. In other words, the dicing or singulation process is, for example, a laser cutting process, a mechanical sawing process, or other suitable processes. After the dicing process, a plurality of conductive bumps 120 is formed on the conductive pads 114, and a singulated package structure PK1 shown in FIG. 7 can be obtained.

As illustrated in FIG. 7, in the package structure PK1, sidewalls of the thermal dissipation structure TX1 are aligned with sidewalls of the first film layer 202, the second film layer 204, the gap-filling layer 108, the first die 104, and the backside redistribution structure 110. Furthermore, in some embodiments, a thickness D1 of the thermal dissipation structure TX1 is in a range of 5 μm to 1,500 μm. In some embodiments, an area of a surface TX1-S1 of the thermal dissipation structure TX1 facing the backside surface 106-BS of the second die 106 is in a range of 10 mm² to 860 mm². In other words, the area of the surface TX1-S1 contacting the second film layer 204 is in a range of 10 mm² to 860 mm². Furthermore, in the illustrated embodiment, one second die 106 is shown to be bonded to one first die 104, whereby the second die 106 is sandwiched in between the first die 104 and the thermal dissipation structure TX1. In some embodiments, a lateral dimension of the second die 106 is smaller than a lateral dimension of the first die 104, and is smaller than a lateral dimension of the thermal dissipation structure TX1.

In the exemplary embodiment, since the package structure PK1 includes a thermal dissipation structure TX1 located over the stacked die structures (first and second dies 104, 106), and a thickness, thermal conductivity, and surface area of the thermal dissipation structure TX1 is controlled within a particular range, an improved thermal solution for 3DIC stacking is provided in the package. As such, heterogeneous integration of low thermal resistance materials may be achieved in the package structure PK1 for improving the performance of the package.

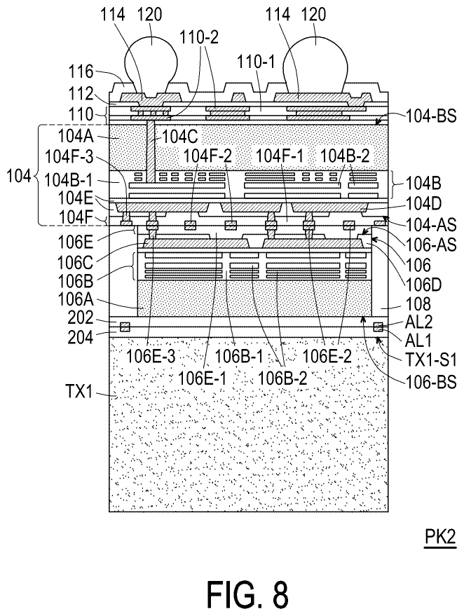

FIG. 8 is a schematic sectional view of a package structure according to some other exemplary embodiments of the present disclosure. The package structure PK2 illustrated in FIG. 8 is similar to the package structure PK1 illustrated in FIG. 7. Therefore, the same reference numerals are used to refer to the same or liked parts, and its detailed description will be omitted herein. The difference between the embodiments is that the package structure PK2 of FIG. 8 further includes a plurality of alignment marks AL1 embedded in the first film layer 202.

As illustrated in FIG. 8, in some embodiments, the alignment marks AL1 are formed and embedded in the second film layer 204, while the alignment marks AL2 are formed and embedded in the first film layer 202. In some embodiments, the alignment marks AL1, AL2 are made of conductive materials, such as copper, or the like. In the exemplary embodiment, the thermal dissipation structure TX1 is disposed on the second dies 106 by joining the first film layer 202 to the second film layer 202. For example, the first film layer 202 is bonded to the second film layer 204 through dielectric-to-dielectric bonding, while the alignment marks AL1 are bonded to the alignment marks AL2 through direct metal-to-metal bonding.

In the exemplary embodiment, since the package structure PK2 includes a thermal dissipation structure TX1 located over the stacked die structures (first and second dies 104, 106), and a thickness, thermal conductivity, and surface area of the thermal dissipation structure TX1 is controlled within a particular range, an improved thermal solution for 3DIC stacking is provided in the package. As such, heterogeneous integration of low thermal resistance materials may be achieved in the package structure PK2 for improving the performance of the package.

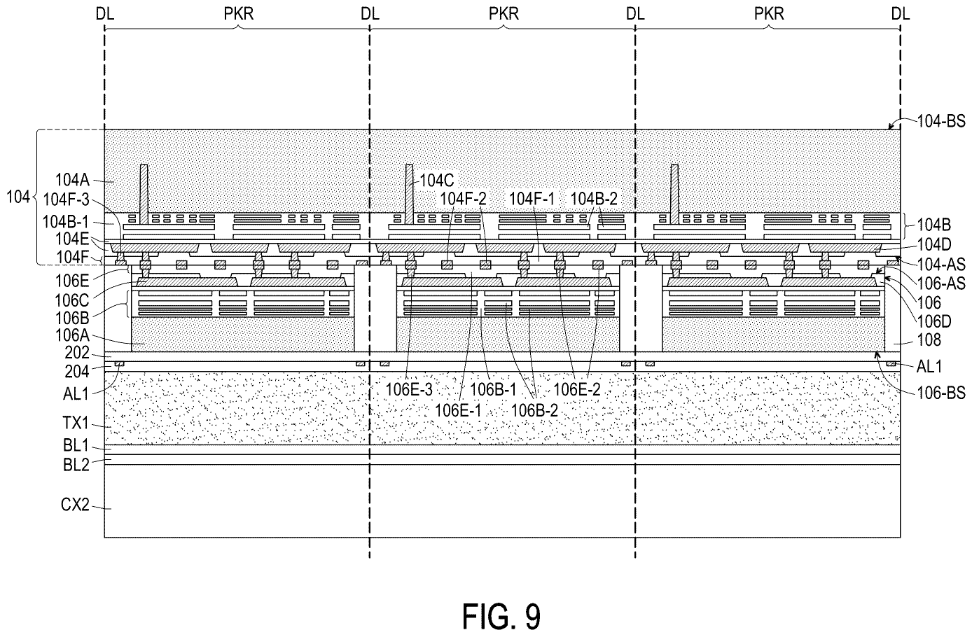

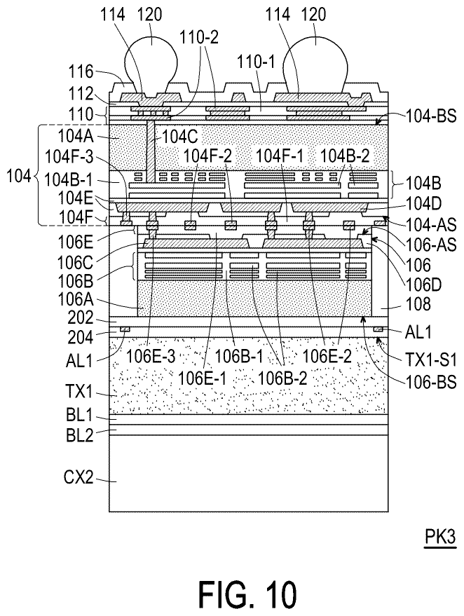

FIG. 9 to FIG. 10 are schematic sectional views of various stages in a method of fabricating a package structure according to some other exemplary embodiments of the present disclosure. The method illustrated in FIG. 9 to FIG. 10 is similar to the method illustrated in FIG. 1 to FIG. 7. Therefore, the same reference numerals are used to refer to the same or liked parts, and its detailed description will be omitted herein.

Referring to FIG. 9, the same steps shown in FIG. 1 and FIG. 2 may be performed to form the first die 104, the second dies 106 and the gap-filling layer 108 on the first carrier CX1. Thereafter, the structure shown in FIG. 2 may be bonded to the thermal dissipation structure TX1 shown in FIG. 9, and the first carrier CX1 may be removed through the debonding process. In the exemplary embodiment, the thermal dissipation structure TX1 is first bonded onto a carrier structure CX2. The carrier structure CX2 may be a silicon carrier, or any suitable carrier for carrying a semiconductor wafer or a reconstituted wafer for the manufacturing method of the semiconductor package. In some embodiments, the thermal dissipation structure TX1 is bonded onto the carrier structure CX2 through a first bonding film BL1 and a second bonding film BL2. For example, the first bonding film BL1 is formed on a surface of the thermal dissipation structure TX1, and the second bonding film BL2 is formed on a surface of the carrier structure CX2. Furthermore, the thermal dissipation structure TX1 is bonded onto the carrier structure CX2 by joining the first bonding film BL1 with the second bonding film BL2 through dielectric-to-dielectric bonding. As illustrated in FIG. 9, after the bonding process, the thermal dissipation structure TX1 is sandwiched in between the backside surface 106-BS of the second die 106 and the carrier structure CX2.

Referring to FIG. 10, the same steps described in FIG. 5 to FIG. 7 may be performed to thin down the backside surface 104-BS of the first die 104, to form the backside redistribution structure 110 on the first die 104, to form conductive pads 114 and dielectric layer 112, 116 on the backside redistribution structure 110, to perform the dicing process, and to form the conductive bumps 120 on the conductive pads 114. For example, after performing the dicing process and forming the conductive bumps 120, the package structure PK3 illustrated in FIG. 10 is accomplished.

In the package structure PK3, the thermal dissipation structure TX1 may be formed with a thickness in a range of 5 μm to 1,500 μm, wherein the thickness of the thermal dissipation structure TX1 may be adjusted depending on the thickness of the carrier structure CX2. In some embodiments, the thickness of the thermal dissipation structure TX1 may be substantially equal to the thickness of the carrier structure CX2. In certain embodiments, the thickness of the thermal dissipation structure TX1 may be greater than the thickness of the carrier structure. In some embodiments, sidewalls of the thermal dissipation structure TX1 are aligned with sidewalls of the carrier structure CX2. Furthermore, in some alternative embodiments, the first bonding film BL1 and the second bonding film BL2 may be omitted, and the thermal dissipation structure TX1 may be bonded to the carrier structure CX2 through the use of adhesives.

In the exemplary embodiment, since the package structure PK3 includes a thermal dissipation structure TX1 located over the stacked die structures (first and second dies 104, 106), and a thickness, thermal conductivity, and surface area of the thermal dissipation structure TX1 is controlled within a particular range, an improved thermal solution for 3DIC stacking is provided in the package. As such, heterogeneous integration of low thermal resistance materials may be achieved in the package structure PK3 for improving the performance of the package.

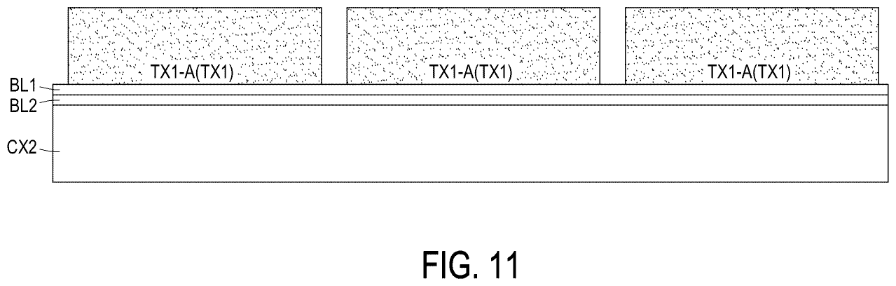

FIG. 11 to FIG. 15 are schematic sectional views of various stages in a method of fabricating a package structure according to some other exemplary embodiments of the present disclosure. The method illustrated in FIG. 11 to FIG. 15 is similar to the method illustrated in FIG. 1 to FIG. 7. Therefore, the same reference numerals are used to refer to the same or liked parts, and its detailed description will be omitted herein.

Referring to FIG. 11, in some embodiments, a thermal dissipation structure TX1 including a plurality of thermal dissipation blocks TX1-A is bonded onto a carrier structure CX2. For example, the thermal dissipation structure TX1 is bonded onto the carrier structure CX2 through a first bonding film BL1 and a second bonding film BL2. The carrier structure CX2, the first bonding film BL1 and the second bonding film BL2 shown in FIG. 11 is the same as that described in FIG. 9 to FIG. 10, thus their details will not be repeated herein. As illustrated in FIG. 11, in some embodiments, the thermal dissipation blocks TX1-A located on the carrier structure CX2 are physically separated from one another.

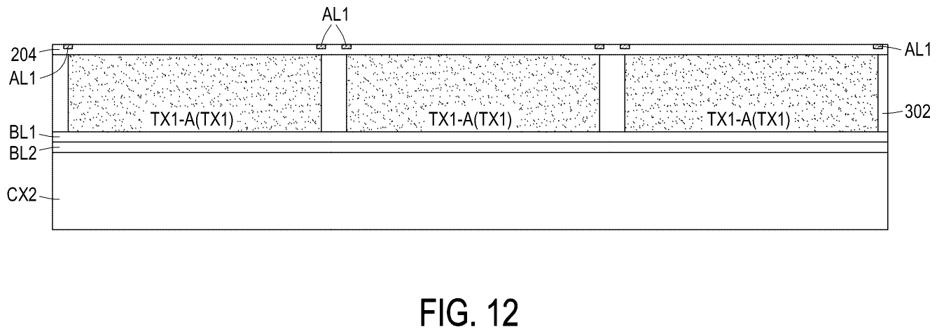

Referring to FIG. 12, after forming the thermal dissipation structure TX1, a dielectric layer 302 is formed on the carrier structure CX2 to laterally surround the thermal dissipation blocks TX1-A. The dielectric layer 302 may be an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as chemical vapor deposition (CVD), atomic layer deposition (ALD), or the like. In some embodiments, after forming the dielectric layer 302, a second film layer 204 including the alignment marks AL1 may be formed over the thermal dissipation structure TX1 (having thermal dissipation blocks TX1-A), and over the dielectric layer 302.

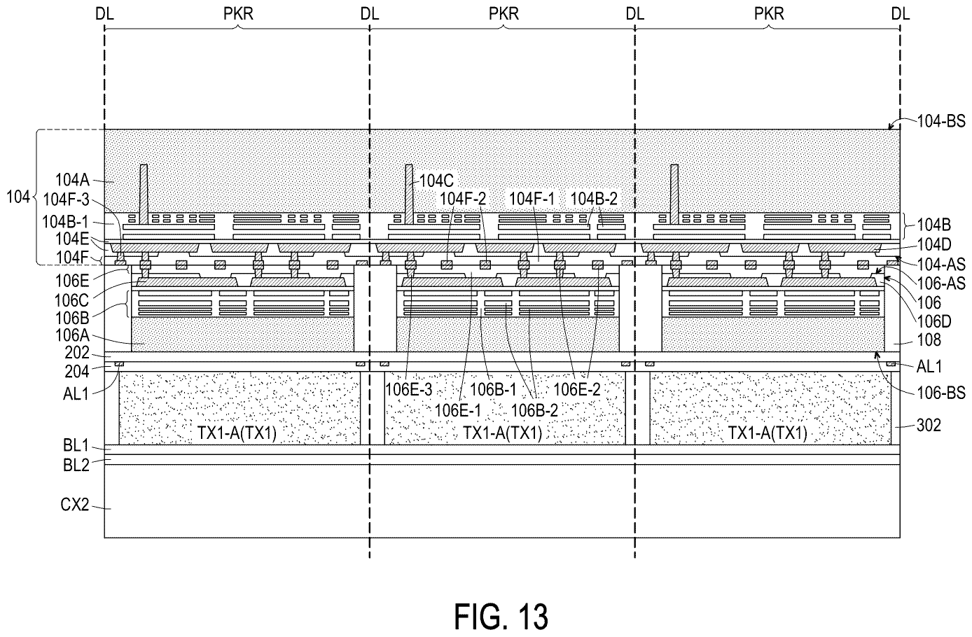

Subsequently, referring to FIG. 13, the same steps shown in FIG. 1 and FIG. 2 may be performed to form the first die 104, the second dies 106 and the gap-filling layer 108 on the first carrier CX1. Thereafter, the structure shown in FIG. 2 may be bonded to the thermal dissipation structure TX1 shown in FIG. 12, and the first carrier CX1 may be removed through the debonding process. For example, the structure shown in FIG. 2 may be bonded to the thermal dissipation structure TX1 through the first film layer 202 and the second film layer 204.

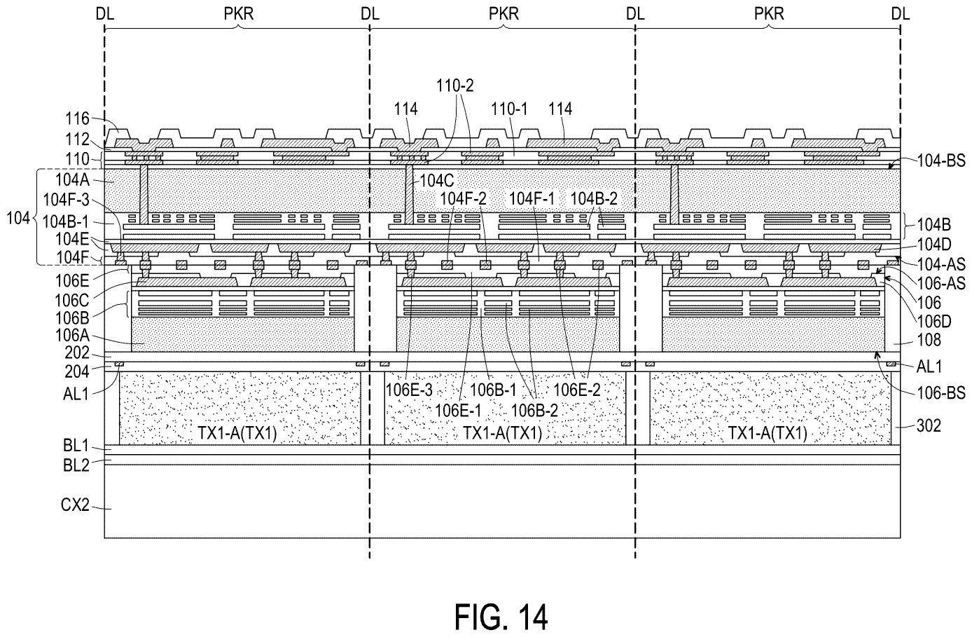

Referring to FIG. 14, after removing the first carrier CX1, the backside surface 104-BS of the first die 104 is thinned down to reveal the through substrate vias 104C. Thereafter, a backside redistribution structure 110 is formed on the backside surface 104-BS of the first die 104. For example, the backside redistribution structure 110 is electrically connected to the through substrate vias 104C of the first die 104. In some embodiments, a dielectric layer 112 is formed on the backside redistribution structure 110, and the dielectric layer is patterned to form openings that reveal the conductive elements 110-2 of the backside redistribution structure 110. Thereafter, conductive pads 114 and a dielectric layer 116 may be formed in the same manner as described in FIG. 5.

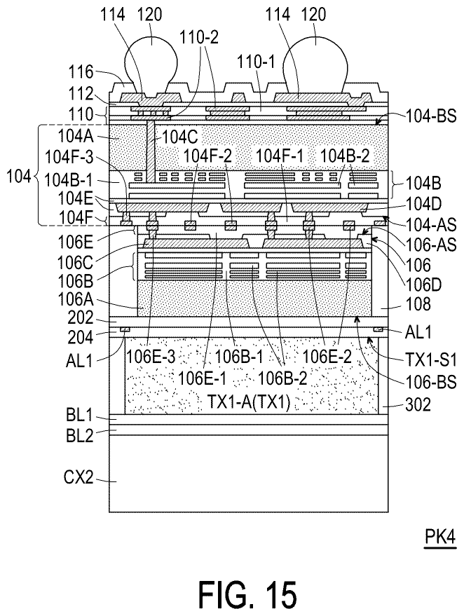

Referring to FIG. 15, the structure shown in FIG. 14 may be diced or singulated along the dicing lines DL, and conductive bumps 120 are then formed on the conductive pads 114 to achieve the package structure PK4. In the package structure PK4, an area of a surface TX1-S1 of the thermal dissipation structure TX1 (e.g. the single thermal dissipation block TX1-A) facing the backside surface 106-BS of the second die 106 is in a range of 10 mm² to 860 mm². Furthermore, a thickness of the thermal dissipation block TX1-A is in a range of 5 μm to 1,500 μm. In some embodiments, a lateral dimension of the thermal dissipation block TX1-A is smaller than a lateral dimension of the carrier structure CX2. Furthermore, the lateral dimension of the thermal dissipation block TX1-A is greater than a lateral dimension of the second die 106.

In the exemplary embodiment, since the package structure PK4 includes a thermal dissipation block TX1-A located over the stacked die structures (first and second dies 104, 106), and a thickness, thermal conductivity, and surface area of the thermal dissipation block TX1-A is controlled within a particular range, an improved thermal solution for 3DIC stacking is provided in the package. As such, heterogeneous integration of low thermal resistance materials may be achieved in the package structure PK4 for improving the performance of the package.

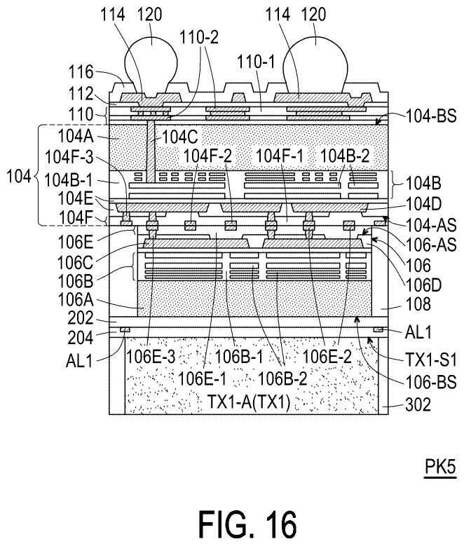

FIG. 16 is a schematic sectional view of a package structure according to some other exemplary embodiments of the present disclosure. The package structure PK5 illustrated in FIG. 16 is similar to the package structure PK4 illustrated in FIG. 15. Therefore, the same reference numerals are used to refer to the same or liked parts, and its detailed description will be omitted herein. The difference between the package structure PK5 and the package structure PK4 is that the carrier structure CX2, the first bonding film BL1 and the second bonding film BL2 are further removed from a surface of the thermal dissipation structure TX1 (or thermal dissipation block TX1-A). In other words, a surface of the thermal dissipation structure TX1 is revealed from the package structure PK5.

In the exemplary embodiment, since the package structure PK5 includes a thermal dissipation block TX1-A located over the stacked die structures (first and second dies 104, 106), and a thickness, thermal conductivity, and surface area of the thermal dissipation block TX1-A is controlled within a particular range, an improved thermal solution for 3DIC stacking is provided in the package. As such, heterogeneous integration of low thermal resistance materials may be achieved in the package structure PK5 for improving the performance of the package.

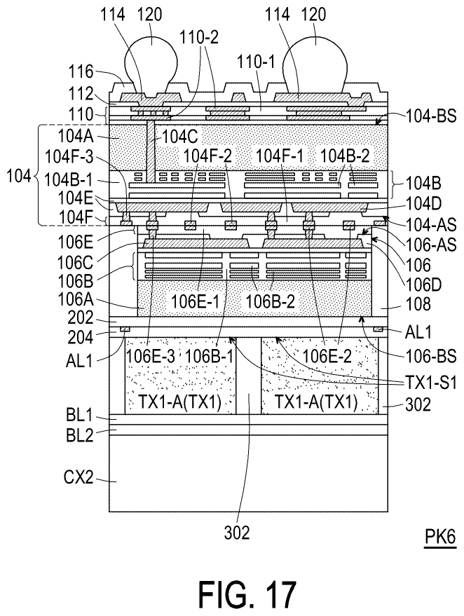

FIG. 17 is a schematic sectional view of a package structure according to some other exemplary embodiments of the present disclosure. The package structure PK6 illustrated in FIG. 17 is similar to the package structure PK4 illustrated in FIG. 15. Therefore, the same reference numerals are used to refer to the same or liked parts, and its detailed description will be omitted herein. The difference between the embodiments is in the design of the thermal dissipation structure TX1. As illustrated in the package structure PK4 of FIG. 15, the thermal dissipation structure TX1 includes a single thermal dissipation block TX1-A arranged on the backside surface 106-BS of one second die 106. However, the disclosure is not limited thereto, and the number of thermal dissipation blocks TX1-A may be adjusted based on design requirements.

As illustrated in FIG. 17, in the exemplary embodiment, the thermal dissipation structure TX1 includes a plurality of thermal dissipation blocks TX1-A arranged on the backside surface 106-BS of one second die 106. For example, the number of thermal dissipation blocks TX1-A may be two or more. In the exemplary embodiment, a sum of an area of a surface TX1-S1 of the plurality of thermal dissipation blocks TX1-A (or the thermal dissipation structure TX1) facing the backside surface 106-BS of the second die 106 is in a range of 10 mm² to 860 mm². Furthermore, a thickness of each of the plurality of thermal dissipation blocks TX1-A is in a range of 5 μm to 1,500 μm, and a thermal conductivity of each of the plurality of thermal dissipation blocks TX1-A is in a range of 120 W/(m·K) to 10,000 W/(m·K). In some embodiments, a lateral dimension of each of the plurality of thermal dissipation blocks TX1-A is smaller than a lateral dimension of the second die 106. In some embodiments, the thermal dissipation blocks TX1-A are partially overlapped with the second die 106. In other words, a portion of the second die 106 is non-overlapped with the thermal dissipation blocks TX1-A.

In the exemplary embodiment, since the package structure PK6 includes a plurality of thermal dissipation block TX1-A located over the stacked die structures (first and second dies 104, 106), and a thickness, thermal conductivity, and surface area of the thermal dissipation blocks TX1-A are controlled within a particular range, an improved thermal solution for 3DIC stacking is provided in the package. As such, heterogeneous integration of low thermal resistance materials may be achieved in the package structure PK6 for improving the performance of the package.

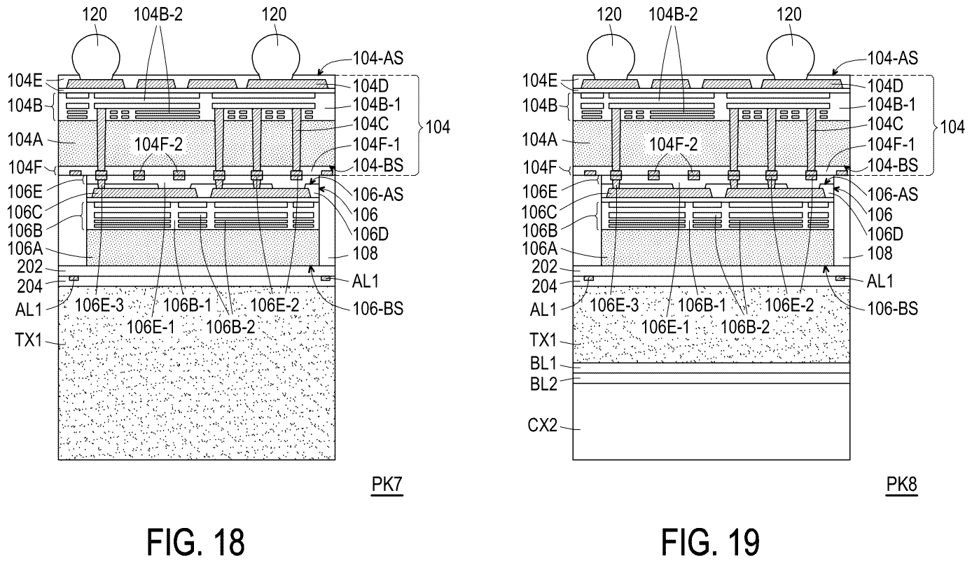

FIG. 18 is a schematic sectional view of a package structure according to some other exemplary embodiments of the present disclosure. The package structure PK7 illustrated in FIG. 18 is similar to the package structure PK1 illustrated in FIG. 7. Therefore, the same reference numerals are used to refer to the same and liked parts, and its detailed description will not be repeated herein. In the embodiment shown in FIG. 7, the first die 104 is bonded to the second die 106 in a face-to-face manner. In other words, an active surface 104-AS of the first die 104 is facing an active surface 106-AS of the second die 106. However, the disclosure is not limited thereto. Referring to FIG. 18, the first die 104 is bonded to the second die 106 in a face-to-back manner. In other words, an active surface 106-AS of the second die 106 is facing a backside surface 104-BS of the first die 104.

As illustrated in FIG. 18, the first bonding layer 104F is formed on a backside of the semiconductor substrate 104A, so that the semiconductor substrate 104A is joined to the second bonding layer 106E through the first bonding layer 104F. In certain embodiments, the conductive bumps 120 are directly formed on the conductive pads 104D of the first die 104, and are located on the active surface 104-AS of the first die 104. In other words, when the first die 104 is bonded to the second die 106 in a face-to-back manner, the formation of the backside redistribution structure 110, the dielectric layers 112, 116 and conductive pads 114 may be omitted.

In the exemplary embodiment, since the package structure PK7 includes a thermal dissipation structure TX1 located over the stacked die structures (first and second dies 104, 106), and a thickness, thermal conductivity, and surface area of the thermal dissipation structure TX1 is controlled within a particular range, an improved thermal solution for 3DIC stacking is provided in the package. As such, heterogeneous integration of low thermal resistance materials may be achieved in the package structure PK7 for improving the performance of the package.

FIG. 19 is a schematic sectional view of a package structure according to some other exemplary embodiments of the present disclosure. The package structure PK8 illustrated in FIG. 19 is similar to the package structure PK7 illustrated in FIG. 18. Therefore, the same reference numerals are used to refer to the same and liked parts, and its detailed description will not be repeated herein. The difference between the embodiments is that in the package structure PK8 shown in FIG. 19, the thermal dissipation structure TX1 is further bonded onto a carrier structure CX2 through a first bonding film BL1 and a second bonding film BL2. The arrangement of the carrier structure CX2, the first bonding film BL1 and the second bonding film BL2 below the thermal dissipation structure TX1 may be the same as that described in FIG. 9 to FIG. 10. Thus, the details of the carrier structure CX2, the first bonding film BL1 and the second bonding film BL2 will not be repeated herein.

In the exemplary embodiment, since the package structure PK8 includes a thermal dissipation structure TX1 located over the stacked die structures (first and second dies 104, 106), and a thickness, thermal conductivity, and surface area of the thermal dissipation structure TX1 is controlled within a particular range, an improved thermal solution for 3DIC stacking is provided in the package. As such, heterogeneous integration of low thermal resistance materials may be achieved in the package structure PK8 for improving the performance of the package.

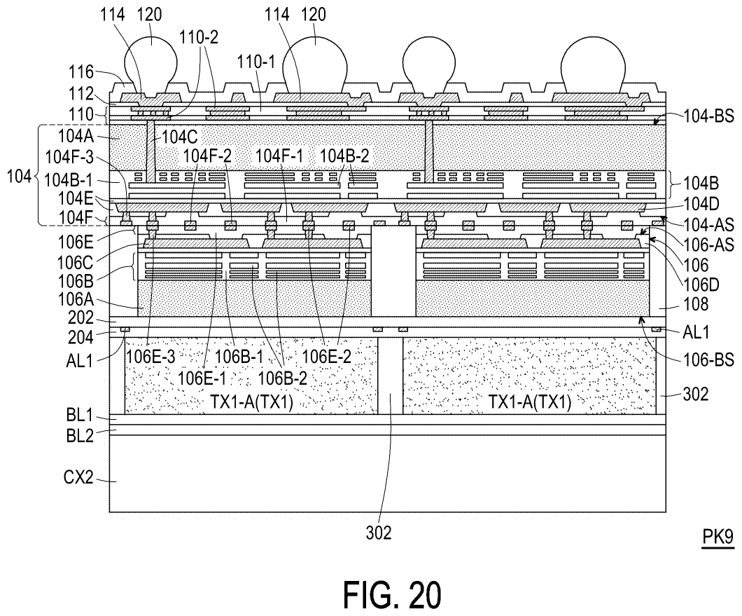

FIG. 20 is a schematic sectional view of a package structure according to some other exemplary embodiments of the present disclosure. The package structure PK9 illustrated in FIG. 20 is similar to the package structure PK4 illustrated in FIG. 15. Therefore, the same reference numerals are used to refer to the same and liked parts, and its detailed description will not be repeated herein. In the embodiment shown in FIG. 15, one second die 106 is shown to be bonded to one first die 104. However, the disclosure is not limited thereto. For example, as shown in FIG. 20, two second dies 106 are bonded to one first die 104. Furthermore, two thermal dissipation blocks TX1-A are respectively located on the backside surfaces 106-BS of the two second dies 106.

From the package structure PK9 shown in FIG. 20, it is noted that a number of second dies 106 arranged on the first die 104 may be adjusted based on product requirements. For example, the number of second dies 106 bonded to the first die 104 may be two or more. Furthermore, a number of thermal dissipation blocks TX1-A arranged on the backside surfaces 106-BS of the second dies 106 may be in correspondence to the number of second dies 106 present.

In the exemplary embodiment, since the package structure PK9 includes a thermal dissipation structure TX1 (having thermal dissipation blocks TX1-A) located over the stacked die structures (first and second dies 104, 106), and a thickness, thermal conductivity, and surface area of the thermal dissipation blocks TX1-A is controlled within a particular range, an improved thermal solution for 3DIC stacking is provided in the package. As such, heterogeneous integration of low thermal resistance materials may be achieved in the package structure PK9 for improving the performance of the package.

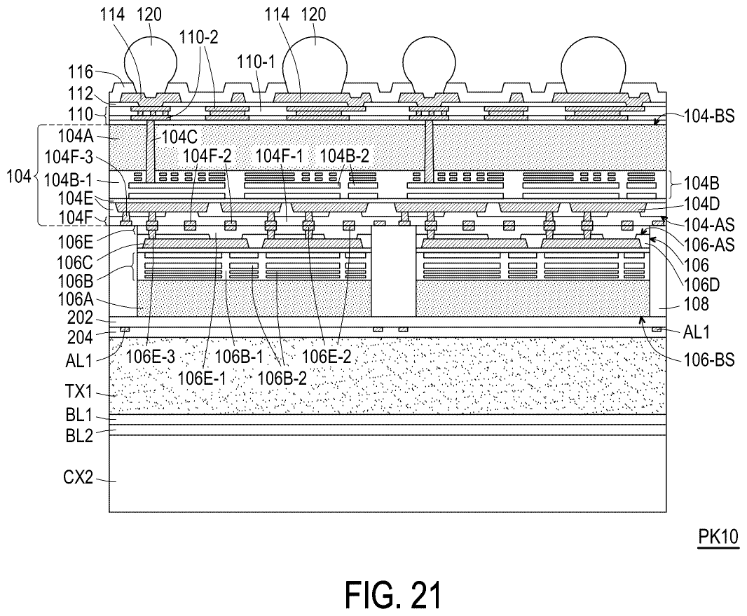

FIG. 21 is a schematic sectional view of a package structure according to some other exemplary embodiments of the present disclosure. The package structure PK10 illustrated in FIG. 21 is similar to the package structure PK9 illustrated in FIG. 20. Therefore, the same reference numerals are used to refer to the same and liked parts, and its detailed description will not be repeated herein. In the package structure PK9 shown in FIG. 20, a plurality of thermal dissipation blocks TX1-A is arranged on the backside surfaces 106-BS of the second dies 106 in correspondence to the number of second dies 106. However, the disclosure is not limited thereto. As shown in FIG. 21, a thermal dissipation structure TX1 (e.g. a single block) is disposed on the backside surfaces 106-BS of the two second dies 106. For example, the sidewalls of the thermal dissipation structure TX1 are aligned with sidewalls of the gap-filling layer 108, and aligned with sidewalls of the first die 104.

In the exemplary embodiment, since the package structure PK10 includes a thermal dissipation structure TX1 located over the stacked die structures (first and second dies 104, 106), and a thickness, thermal conductivity, and surface area of the thermal dissipation structure TX1 is controlled within a particular range, an improved thermal solution for 3DIC stacking is provided in the package. As such, heterogeneous integration of low thermal resistance materials may be achieved in the package structure PK10 for improving the performance of the package.

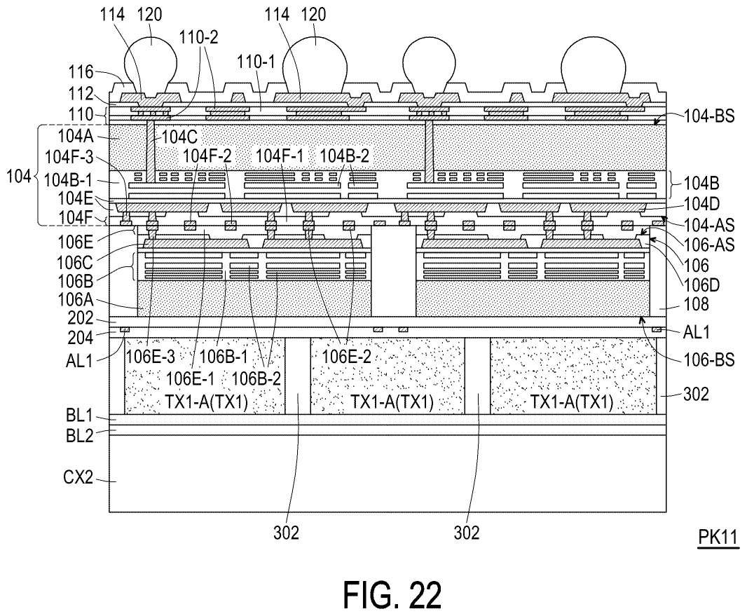

FIG. 22 is a schematic sectional view of a package structure according to some other exemplary embodiments of the present disclosure. The package structure PK11 illustrated in FIG. 22 is similar to the package structure PK9 illustrated in FIG. 20. Therefore, the same reference numerals are used to refer to the same and liked parts, and its detailed description will not be repeated herein. In the package structure PK9 shown in FIG. 20, a lateral dimension of each of the thermal dissipation blocks TX1-A is greater than a lateral dimension of each of the second dies 106. However, the disclosure is not limited thereto. In some embodiments, as illustrated in FIG. 22, a lateral dimension of each of the thermal dissipation blocks TX1-A is smaller than a lateral dimension of each of the second dies 106. Furthermore, a number of thermal dissipation blocks TX1-A is greater than a number of second dies 106. For example, three thermal dissipation blocks TX1-A may be located on the backside surfaces 106-BS of two second dies 106.

In the exemplary embodiment, since the package structure PK11 includes a thermal dissipation structure TX1 (having thermal dissipation blocks TX1-A) located over the stacked die structures (first and second dies 104, 106), and a thickness, thermal conductivity, and surface area of the thermal dissipation blocks TX1-A is controlled within a particular range, an improved thermal solution for 3DIC stacking is provided in the package. As such, heterogeneous integration of low thermal resistance materials may be achieved in the package structure PK11 for improving the performance of the package.

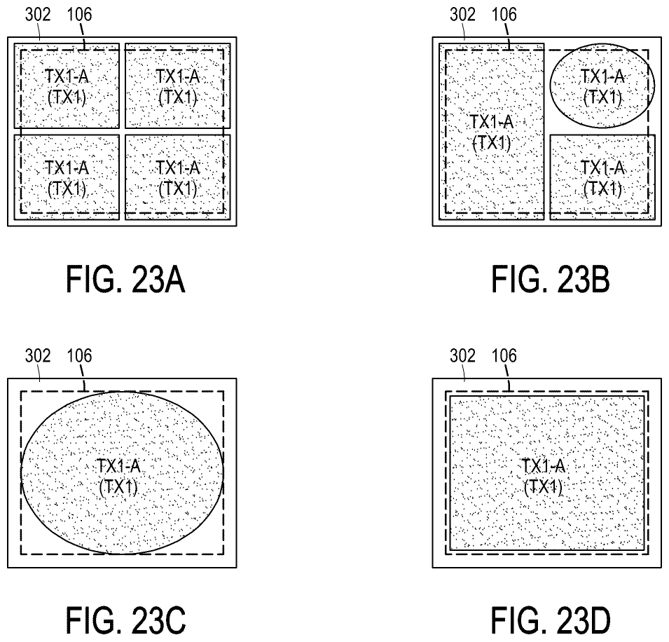

FIG. 23A to FIG. 23D are schematic bottom views of the package structure according to various embodiments of the present disclosure. For example, a bottom view illustrating the relative positions of the thermal dissipation structure TX1 (thermal dissipation blocks TX1-A) and the second die 106 are shown in FIG. 23A to FIG. 23D. For package structures that includes one or a plurality of thermal dissipation blocks TX1-A located on the backside surfaces 106-BS of the second die 106 (e.g. PK4, PK5, PK6, PK9, PK11), the thermal dissipation blocks TX1-A may have various exemplary designs as shown in FIG. 23A to FIG. 23D.

Referring to FIG. 23A, in one embodiment, there may be four thermal dissipation blocks TX1-A located on the backside surface 106-BS of the second die 106. The four thermal dissipation blocks TX1-A are separated from one another by the dielectric layer 302. Furthermore, the four thermal dissipation blocks TX1-A are respectively overlapped with four corners of the second die 106. In some embodiments, portions of the second die 106 may be non-overlapped with the four thermal dissipation blocks TX1-A.

Referring to FIG. 23B, in another embodiment, there may be three thermal dissipation blocks TX1-A located on the backside surface 106-BS of the second die 106. For example, the three thermal dissipation blocks TX1-A may have different shapes, such as a rectangular shape, a square shape, a circular or oval shape. The three thermal dissipation blocks TX1-A are separated from one another by the dielectric layer 302.

Referring to FIG. 23C and FIG. 23D, in some other embodiments, there is one thermal dissipation block TX1-A located on the backside surface 106-BS of one second die 106. For example, the thermal dissipation block TX1-A has a circular or oval shape (FIG. 23C). Alternatively, the thermal dissipation block TX1-A has a shape that substantially corresponds to a shape of the second die 106 (FIG. 23D). In other words, sidewalls of the thermal dissipation block TX1-A may be aligned with sidewalls of the second die 106. In the above embodiments, a center position of the thermal dissipation block TX1-A is aligned with a center position of the second die 106. Furthermore, the thermal dissipation block TX1-A is overlapped with at least 50% of an area of the backside surface 106-BS of the second die 106. In various embodiments, the thermal dissipation block TX1-A is overlapped with 50%, 55%, 60%, 65%, 70%, 75%, 80%, 85%, 90%, 95% or 100% of an area of the backside surface 106-BS of the second die 106. In some other embodiments, the thermal dissipation block TX1-A is overlapped with 50% to 99% of an area of the backside surface 106-BS of the second die 106.

From the embodiments illustrated in FIG. 23A to FIG. 23D, it is noted that when thermal dissipation blocks TX1-A are present in the package structure, the number, shape and arrangement of the thermal dissipation blocks TX1-A may be adjusted based on product requirements. Furthermore, when two or more second dies 106 are bonded to the first die 104, the design of the thermal dissipation blocks TX1-A located on the backside surface 106-BS of each of the second dies 106 may be the same or different, which may be adjusted based on product requirements. However, the backside surface 106-BS of each of the second dies 106 is at least overlapped with one or more of the thermal dissipation blocks TX1-A.

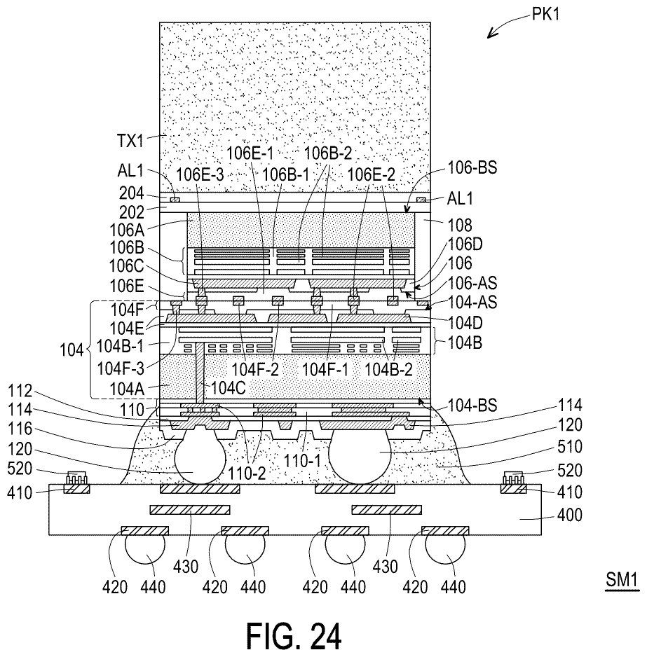

FIG. 24 is a schematic sectional view of a semiconductor package according to some exemplary embodiments of the present disclosure. Referring to FIG. 24, the package structure PK1 obtained in FIG. 7 is mounted or attached onto a circuit substrate 400 through the conductive bumps 120. Although the package structure PK1 is used as an example herein for bonding to the circuit substrate 400, it is noted that the other package structures described above (e.g. PK2, PK3, PK4, PK5, PK6, PK7, PK8, PK9, PK10 and PK11) may be mounted on the circuit substrate 400 in the same manner.

As illustrated in FIG. 24, in some embodiments, the circuit substrate 400 includes contact pads 410, contact pads 420, metallization layers 430, and vias (not shown). In some embodiments, the contact pads 410 and the contact pads 420 are respectively distributed on two opposite sides of the circuit substrate 400, and are exposed for electrically connecting with later-formed elements/features. In some embodiments, the metallization layers 430 and the vias are embedded in the circuit substrate 400 and together provide routing function for the circuit substrate 400, wherein the metallization layers 430 and the vias are electrically connected to the contact pads 410 and the contact pads 420. In other words, at least some of the contact pads 410 are electrically connected to some of the contact pads 420 through the metallization layers 430 and the vias. In some embodiments, the contact pads 410 and the contact pads 420 may include metal pads or metal alloy pads. In some embodiments, the materials of the metallization layers 430 and the vias may be substantially the same or similar to the material of the contact pads 410 and the contact pads 420.

Furthermore, in some embodiments, the package structure PK1 is bonded to the circuit substrate 400 through physically connecting the conductive bumps 120 and the contact pads 410 to form a stacked structure. In certain embodiments, the package structure PK1 is electrically connected to the circuit substrate 400. In some embodiments, the circuit substrate 400 is such as an organic flexible substrate or a printed circuit board. In some embodiments, a plurality of conductive balls 440 are respectively formed on the substrate 400. As illustrated in FIG. 24, for example, the conductive balls 440 are connected to the contact pads 420 of the circuit substrate 400. In other words, the conductive balls 440 are electrically connected to the circuit substrate 400 through the contact pads 420. Through the contact pads 410 and the contact pads 420, some of the conductive balls 440 are electrically connected to the package structure PK1. In some embodiments, the conductive balls 440 are, for example, solder balls or ball grid array (BGA) balls.

As further illustrated in FIG. 24, in some embodiments, passive devices 520 (integrated passive device or surface mount devices) may be mounted on the circuit substrate 400. For example, the passive devices 520 may be mounted on the contact pads 410 of the circuit substrate 400 through a soldering process. The disclosure is not limited thereto. In certain embodiments, the passive devices 520 may be mounted on the circuit substrate 400 surrounding the package structure PK1. In some embodiments, an underfill structure 510 is formed to fill up the spaces in between the circuit substrate 400 and the package structure PK1. In certain embodiments, the underfill structure 510 fills up the spaces in between adjacent conductive bumps 120 and covers the conductive bumps 120. For example, the underfill structure 510 surrounds the plurality of conductive bumps 120. In some embodiments, the passive devices 520 is exposed by the underfill structure 510, and kept a distance apart from the underfill structure 510. In other words, the underfill structure 510 does not cover the passive devices 520. Up to here, a semiconductor package SM1 in accordance with some embodiments of the present disclosure is accomplished.

In the above-mentioned embodiments, the semiconductor package includes a package structure having a thermal dissipation structure (or thermal dissipation blocks) located over the stacked die structures (first and second dies), and a thickness, thermal conductivity, and surface area of the thermal dissipation structure is controlled within a particular range. As such, an improved thermal solution for 3DIC stacking is provided in the package. Furthermore, heterogeneous integration of low thermal resistance materials may be achieved in the semiconductor package for improving the performance of the package.

In accordance with some embodiments of the present disclosure, a semiconductor package includes a first die, at least one second die and a thermal dissipation structure. The first die has a first bonding layer. The second die has a second bonding layer, wherein the second die is disposed on the first die, and the second bonding layer is bonded to the first bonding layer. The thermal dissipation structure is disposed on a backside surface of the at least one second die, wherein a thickness of the thermal dissipation structure is in a range of 5 μm to 1,500 μm.

In accordance with some other embodiments of the present disclosure, a semiconductor package includes a thermal dissipation structure, a first die, a second die, a first film layer and a second film layer. The first die is located on the thermal dissipation structure. The second die is located in between the thermal dissipation structure and the first die, and electrically connected to the first die. The first film layer is located on a backside surface of the second die and contacting the backside surface. The second film layer is located on a first surface of the thermal dissipation structure and contacting the first surface, wherein the second film layer is joined with the first film layer.

In accordance with yet another embodiment of the present disclosure, a method of fabricating a semiconductor package is disclosed. The method includes the following steps. A first die is formed, wherein the first die has a first bonding layer. At least one second die is formed, wherein the second die has a second bonding layer. The at least one second die is bonded on the first die, wherein the second bonding layer is bonded to the first bonding layer. The at least one second die is attached onto a thermal dissipation structure, wherein the thermal dissipation structure is disposed on a backside surface of the at least one second die, and a thickness of the thermal dissipation structure is in a range of 5 μm to 1,500 μm.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first die having a first bonding layer;
at least one second die having a second bonding layer, wherein the at least one second die is disposed on the first die, and the second bonding layer is bonded to the first bonding layer; and
a thermal dissipation structure disposed on a backside surface of the at least one second die, wherein a thermal conductivity of the thermal dissipation structure is in a range of 120 W/(m·K) to 10,000 W/(m·K), a thickness of the thermal dissipation structure is in a range of 5 μm to 1,500 μm, and an area of a surface of the thermal dissipation structure facing the backside surface of the at least one second die is in a range of 10 mm² to 860 mm².

2. The semiconductor package according to claim 1, wherein the at least one second die comprises two second dies disposed on the first die, and the thermal dissipation structure is disposed on the backside surface of the two second dies.

3. The semiconductor package according to claim 1, further comprising a first film layer and second film layer located in between the backside surface of the at least one second die and the surface of the thermal dissipation structure, wherein an alignment mark is embedded in the first film layer or the second film layer.

4. The semiconductor package according to claim 1, wherein the thermal dissipation structure comprises a single crystal diamond (SCD) material.

5. The semiconductor package according to claim 1, further comprising a gap-filling layer laterally surround the at least one second die, wherein sidewalls of the gap-filling layer are aligned with sidewalls of the thermal dissipation structure.

6. The semiconductor package according to claim 1, further comprising a carrier structure located on the thermal dissipation structure, wherein the thermal dissipation structure is sandwiched in between the backside surface of the at least one second die and the carrier structure.

7. The semiconductor package according to claim 6, wherein a lateral dimension of the thermal dissipation structure is smaller than a lateral dimension of the carrier structure.

8. The semiconductor package according to claim 1, wherein the thermal dissipation structure comprises a plurality of thermal dissipation blocks, the plurality of thermal dissipation blocks is physically separated from one another, and a dielectric layer is laterally surrounding the plurality of thermal dissipation blocks.

9. A semiconductor package, comprising:
a thermal dissipation structure;
a first die located on the thermal dissipation structure;
a second die located in between the thermal dissipation structure and the first die, and electrically connected to the first die;
a first film layer located on a backside surface of the second die and contacting the backside surface;
a second film layer located on a first surface of the thermal dissipation structure and contacting the first surface, wherein the second film layer is joined with the first film layer; and
a plurality of alignment marks embedded in the first film layer and/or the second film layer.

10. The semiconductor package according to claim 9, wherein a thickness of the thermal dissipation structure is greater than a thickness of the second die.

11. The semiconductor package according to claim 9, wherein a lateral dimension of the thermal dissipation structure is smaller than a lateral dimension of the first die.

12. The semiconductor package according to claim 9, further comprising a carrier structure located on a second surface of the thermal dissipation structure, wherein the second surface is opposite to the first surface.

13. The semiconductor package according to claim 12, wherein sidewalls of the thermal dissipation structure are aligned with sidewalls of the carrier structure.

14. The semiconductor package according to claim 9, wherein a thickness of the thermal dissipation structure is in a range of 5 μm to 1,500 μm, and an area of the first surface of the thermal dissipation structure is in a range of 10 mm² to 860 mm².

15. The semiconductor package according to claim 9, wherein:
the first die comprises an active surface and a backside surface opposite to the active surface;
the second die comprises an active surface and the backside surface opposite to the active surface, and
wherein the active surface of the second die is facing the active surface of the first die.

16. A method of fabricating a semiconductor package, comprising:
forming a first die having a first bonding layer;
forming at least one second die having a second bonding layer;
bonding the at least one second die on the first die, wherein the second bonding layer is bonded to the first bonding layer;
attaching the at least one second die onto a thermal dissipation structure, wherein the thermal dissipation structure is disposed on a backside surface of the at least one second die, and wherein a thermal conductivity of the thermal dissipation structure is in a range of 120 W/(m·K) to 10,000 W/(m·K), a thickness of the thermal dissipation structure is in a range of 5 μm to 1,500 μm, and an area of a first surface of the thermal dissipation structure facing the backside surface of the at least one second die is in a range of 10 mm² to 860 mm².

17. The method according to claim 16, wherein after bonding the at least one second die on the first die, the method further comprises forming a gap-filling layer laterally surrounding the at least one second die.

18. The method according to claim 16, wherein prior to attaching the at least one second die onto the first surface of the thermal dissipation structure, the method further comprises attaching a second surface of the thermal dissipation structure onto a carrier structure, and wherein the second surface is opposite to the first surface.

19. The method according to claim 16, wherein prior to attaching the at least one second die onto the thermal dissipation structure, the method further comprises forming a dielectric layer laterally surrounding the thermal dissipation structure.

20. The method according to claim 19, wherein the thermal dissipation structure is formed with a plurality of thermal dissipation blocks physically separated from one another, and wherein the dielectric layer is physically separating the plurality of thermal dissipation blocks.
